(19) United States
(12) Patent Application Publication
(10) Pub. No.: US 2025/0258297 A1
(43) Pub. Date: Aug. 14, 2025

(54) ParaDrop Operation Transponder

(71) Applicant: ZeroFoxWorx LLC, Sheridan, WY (US)

(72) Inventors: Christine E. Lesko, Tucson, AZ (US); Mark Zepeda, Tucson, AZ (US)

(73) Assignee: ZeroFoxWorx LLC, Sheridan, WY (US)

(21) Appl. No.: 19/048,940

(22) Filed: Feb. 9, 2025

Related U.S. Application Data
(60) Provisional application No. 63/552,066, filed on Feb. 9, 2024.

(51) Int. Cl. G01S 19/18; G01S 19/35; H05K 5/00

(52) U.S. Cl. CPC G01S 19/18; G01S 19/35; H05K 5/0047; H05K 5/0069

(57) ABSTRACT

The ParaDrop Operation Transponder (100) is a device that increases safety, visibility, and separation of paradrop operations by aircraft and air traffic controllers at high-volume airports and remote off-airport DZs (drop zones) for use at all altitudes and during night and day operations. The ParaDrop Operation Transponder (100) provides aircraft the ability to avoid parachute canopies utilized during high speed free fall, all weather and/or night operations. When the aircraft cannot physically see the parachute canopies, the aircraft can still locate the ParaDrop Operation Transponder (100) location on their traffic in-cockpit screens in real time. The GPS transponder (700) within the device is an ADS-B/Mode-S out device that enables the aerial jumper (90) to be detected by Secondary Surveillance Radar (SSR), Traffic Collision Avoidance Systems (TCAS), and ADS-B IN receivers.

### CROSS-REFERENCE TO RELATED APPLICATIONS

Not Applicable

### STATEMENT REGARDING FEDERALLY SPONSORED R & D

Not Applicable

### THE NAMES OF THE PARTIES TO A JOINT RESEARCH AGREEMENT

Not Applicable

### REFERENCE TO A “SEQUENCE LISTING,” A TABLE, OR A COMPUTER PROGRAM

Not Applicable

### STATEMENT REGARDING PRIOR DISCLOSURES BY AN INVENTOR OR JOINT INVENTOR

Not Applicable

### BRIEF DESCRIPTION OF THE SEVERAL VIEWS OF THE DRAWING

FIG. 1 shows a isometric right top view of the ParaDrop Operational Transponder (100);

FIG. 2 shows a isometric left bottom view of the ParaDrop Operational Transponder (100);

FIG. 3 shows a right view of the ParaDrop Operational Transponder (100);

FIG. 4 shows a left view of the ParaDrop Operational Transponder (100);

FIG. 5 shows a front view of the ParaDrop Operational Transponder (100);

FIG. 6 shows a back view of the ParaDrop Operational Transponder (100);

FIG. 7 shows an exploded front right isometric view of the ParaDrop Operational Transponder (100);

FIG. 8 shows an exploded front view of the ParaDrop Operational Transponder (100);

FIG. 9 shows an exploded side view of the ParaDrop Operational Transponder (100);

FIG. 10 shows an isometric view of the main circuit board (300), showing the outside data/power connector (350) and the inside data/power connector (355);

FIG. 11 shows a top view of the main circuit board (300);

FIG. 12 shows a isometric view of the secondary circuit board (600), showing the GPS status indication (620) and the power level status indicator (630);

FIG. 13 shows a side view of the secondary circuit board (600) showing the GPS status indication (620) and the power level status indicator (630).

GLOSSARY

| | |
|---|---|
| ADS-B | Automatic Dependent Surveillance-Broadcast |
| AGL | above ground level |
| ATC | air traffic control |
| DZ | drop zone |
| DZSO | drop zone safety officers |
| FAA | Federal Aviation Administration |
| GLONASS | GLObalnaya NAvigatsionnaya Sputnikovaya |
| | Sistema in Russian |
| GPAD | Guided Precision Airdrop System (Ground |
| | launched or air launched autonomous cargo |
| | pallets) |
| GNSS | Global navigation satellite system |
| GPS | Global Positioning System |
| HALO | high altitude-low opening |
| HAHO | high altitude-high opening |
| JPADS | Joint Precision Airdrop System |
| NAS | National Airspace System |
| NOTAMs | Notice to Air Missions |
| UAS | unmanned aircraft systems |

### BACKGROUND OF INVENTION

### 1 General Parachuting and Skydiving Information

Parachuting and skydiving is a method of transiting from a high point in an atmosphere to the ground or ocean surface with the aid of gravity, involving the control of speed during the descent using a parachute or parachutes.

For human skydiving, it may involve a phase of free-falling (the skydiving segment) which is a period when the parachute has not yet been deployed, and the body gradually accelerates to terminal velocity.

Jump altitudes typically range from 10,000′ to 18,000′. HAHO/HALO jump altitudes can be up to 30,000′. It takes just over a minute of free-fall to arrive at parachute opening altitudes of 4,000′ AGL to 2,000′ AGL. Once the parachute opens, the rate of descent slows from 120 mph (roughly 10,500 fpm) to a normal descent rate of 1,000 fpm. Although even with a minimum parachute opening altitude of 2,000′ AGL, aerial jumpers are generally well above normal traffic pattern altitudes for airports; landing patterns for aerial jumpers are generally contained well within aircraft traffic patterns.

A concern for parachuting and skydiving is that aircraft and air traffic controllers do not have visibility of individual jumpers, but rather, only have a generalized idea that a flight area is known for frequent parachute operation and that a plane with jumpers is operating in that flight area.

A Notice to Air Missions (NOTAMs) contains information essential to personnel concerned with flight operations but not known far enough in advance to be publicized by other means. It states the abnormal status of a component of the National Airspace System (NAS)—not the normal status. NOTAMs indicate the real-time and abnormal status of the NAS impacting every user. NOTAMs concern the establishment, condition, or change of any facility, service, procedure, or hazard in the NAS. NOTAMs have a unique language using special contractions to make communication more efficient.

NOTAMs provide notice of a 20-30 mile ring around the airdrop location, a large volume, which provides little actionable information to understand where the jumpers are located at any given time after the airdrop.

A rather thorough noticing procedure needs to be followed before a jump. At nontowered fields, the nearest ATC facility must be notified at least one hour in advance but not more than 24 hours in advance. The operation must also have approval from airport management. As for the actual jump, ATC must be notified five minutes prior to drop. Surprisingly, jump operations are not always required to provide NOTAMs.

Without an open parachute, aerial jumpers are extremely hard to spot due to their small size and high speed. Even with an open parachute, aerial jumpers are difficult to spot in night skydiving. Furthermore, aerial jumpers have the ability to change directions. It is impossible for pilots to spot aerial jumpers, and aerial jumpers might use night vision goggles that provide minimal awareness. Thus, there is a real possibility for a mid-air collision between aerial jumpers with aircraft.

This possibility increases in magnitude when jumpers attempt to enter controller air space. Parachute jumps are not authorized into controlled airspace, except without explicit permission and coordination from the controlling ATC agency. When operating in controlled airspace, jump pilots are required to communicate with ATC at least two minutes prior to jump operations. See 14 CFR 105. This makes for a complex time consuming coordination to allow operations that could be time sensitive, such as rescue operations, aerial cargo, and JPADS/GPADS delivery.

Aerial cargo is composed of a parachute decelerator and a load container that is dropped without a guidance device.

JPADS/GPADS integrate a parachute decelerator, an autonomous guidance unit and a load container or pallet to create a system that can accurately deliver critical supplies with great precision along a predetermined glide and flight path. The system consists of two weight classes: 2,000 pounds (2K) and 10,000 pounds (10K). The guidance system uses military Global Positioning System (GPS) data for precise navigation and interfaces with a wirelessly updatable mission planning module onboard the aircraft to receive real-time weather data and compute multiple aerial release points. The guidance system may also be ground controlled.

### 2 Automatic Dependent Surveillance-Broadcast (ADS-B): Enhancing Air Traffic Surveillance and Communication

### 2.1 Introduction

Automatic Dependent Surveillance-Broadcast (ADS-B) is a modern and transformative technology that has significantly improved air traffic surveillance and communication in the aviation industry. ADS-B relies on satellite navigation and advanced communication systems to provide accurate and real-time information about an aircraft's position, velocity, and other essential parameters. This section aims to explore the fundamental principles of ADS-B, its components, and the benefits it offers to both airplanes and air traffic controllers.

### 2.2 Overview of ADS-B

ADS-B is a surveillance technology that enables aircraft to broadcast their identity, position, altitude, and other information derived from onboard systems. Unlike traditional radar systems, which rely on ground-based radar stations to track aircraft, ADS-B allows airplanes to automatically determine and broadcast their information via a data link. This information is then received by other aircraft and ground stations equipped with ADS-B receivers. The key components of ADS-B include the aircraft's avionics system, the data link for broadcasting information, and the ground infrastructure for receiving and processing the transmitted data.

### 2.3 Working Principles

ADS-B relies on the Global Navigation Satellite System (GNSS) for precise positioning. The aircraft's avionics system calculates its position using signals from satellite constellations such as GPS, GLONASS, or Galileo. The calculated information, along with additional data such as altitude, speed, and heading, is then transmitted periodically through a data link. There are two types of ADS-B messages: ADS-B Out and ADS-B In.
ADS-B Out: This is the broadcast function where the aircraft transmits its information to other aircraft and ground stations. The transmitted data includes the aircraft's identity, position, velocity, and intent information.
ADS-B In: This function allows an aircraft to receive and display the ADS-B information from other nearby aircraft. It enhances situational awareness for pilots by providing a more comprehensive view of the airspace.

### 2.4 Benefits of ADS-B

Benefits of the use of ADS-B include:
Improved Situational Awareness: ADS-B Out enhances situational awareness for the pilots, aerial jumpers, and air traffic controllers all sharing the same airspace. Real-time and accurate information about an aircraft or aerial jumper position reduces the risk of collisions and allows for more efficient air traffic management.
Increased Safety: By providing up-to-date information about aircraft positions, ADS-B contributes to a safer aviation environment. Pilots and air traffic controllers can receive timely traffic alerts and take necessary actions to avoid potential conflicts.
Efficient Air Traffic Management: ADS-B enables more precise and efficient air traffic management. Air traffic controllers can optimize routes, reduce separation distances, and enhance overall airspace capacity.
Cost-Effective: ADS-B is a cost-effective solution compared to traditional radar systems. The technology is more reliable, requires less maintenance, and offers greater coverage, especially in remote or oceanic areas.

### 2.5 Conclusion

While ADS-B represents a crucial advancement in air traffic surveillance and communication, offering benefits such as improved situational awareness, increased safety, and efficient air traffic management. ADS-B does not yet provide for aerial jumpers or unmanned aircraft in controlled airspace.

As the aviation industry continues to evolve, ADS-B will play a central role in shaping the future of air transportation by contributing to a safer, more interconnected, and technologically advanced airspace.

### 3 the FAA Mandate for ADS-B Implementation

In recognition of the significant safety and operational benefits offered by ADS-B, the Federal Aviation Administration (FAA) in the United States made the decision to mandate its implementation for certain aircraft. The mandate, known as the ADS-B Out rule, was established to enhance airspace surveillance, reduce the risk of collisions, and modernize the overall air traffic management system.

### 3.1 Timeline of the ADS-B Mandate

The timeline of the ADS-B mandate is:
Rulemaking Process: The process leading to the ADS-B mandate began with the FAA's rulemaking activities. The FAA initiated the rulemaking process well in advance, allowing for industry input, collaboration, and adjustments to the proposed regulations.
Publication of the Final Rule: The final rule mandating ADS-B Out capabilities for certain aircraft was published by the FAA on May 28, 2010. This rule, officially known as 14 CFR 91.225 and 14 CFR 91.227, outlined the specific requirements and deadlines for ADS-B Out equipage.
Implementation Deadlines: The FAA established a phased approach for compliance with the ADS-B Out mandate. The key deadlines were set for Jan. 1, 2020 and required that aircraft operating in certain airspace, including most controlled airspace and certain busy airspace areas, be equipped with ADS-B Out technology.

### 3.2 Key Components of the ADS-B Mandate

The key components of the ADS-B mandate are:
Equipage Requirements: The mandate required that aircraft operating in designated airspace must be equipped with FAA-certified ADS-B Out avionics. These avionics systems needed to meet specific technical standards to ensure compatibility and interoperability within the national airspace system.
Covered Aircraft: The mandate applied to a broad range of aircraft, including most turbine-powered aircraft, as well as aircraft with a maximum takeoff weight exceeding 5,500 pounds or a cruise speed greater than 250 knots. Certain exceptions were made for aircraft operating in areas without ADS-B coverage.
Designated Airspace: The mandate focused on airspace where ADS-B surveillance was deemed essential for enhancing safety and efficiency. This included airspace above 10,000 feet, Class A airspace, and airspace within 30 nautical miles of designated busy airports.

### 3.3 Rationale for the Mandate

The FAA's decision to mandate ADS-B was grounded in the pursuit of enhancing the safety and efficiency of the national airspace system. By requiring aircraft to broadcast their precise position and other essential information via ADS-B, the FAA aimed to modernize air traffic surveillance, reduce the risk of mid-air collisions, and facilitate more effective air traffic management.

### 3.4 Benefits of the ADS-B Mandate

The benefits of the ADS-B mandate are:
Enhanced Safety: The widespread adoption of ADS-B Out technology contributes to increased situational awareness for pilots and air traffic controllers, leading to a safer aviation environment.
Improved Traffic Management: ADS-B enables more precise tracking of aircraft, allowing for better traffic management, reduced separation distances, and overall improved airspace efficiency.
Interoperability: The mandate fostered the standardization and interoperability of ADS-B technology, ensuring a seamless integration of equipped aircraft into the national airspace system.

### 3.5 Conclusion

In conclusion, the FAA's decision to mandate ADS-B in 2020 was a significant step toward modernizing and enhancing the safety of the U.S. airspace system. The implementation deadlines provided a clear timeline for aircraft operators to equip their aircraft with ADS-B Out technology, ushering in a new era of surveillance and communication in aviation. Currently, in 2025, ADS-B is not mandated for parachutists or certain unmanned aircraft systems UAS requirements are based on size and weight of the drone. However, technological improvements such as these included in this patent application merit a reconsideration for such a mandate.

### 4 Need

The challenge of detecting and tracking aerial jumpers in the air poses unique difficulties for both airplanes and air traffic controllers. While modern aviation technologies, such as radar, excels at tracking larger aircraft, they are not specifically designed to address the characteristics and limitations associated with tracking individual aerial jumpers. Several factors contribute to the difficulty in spotting and tracking aerial jumpers effectively:
Size and Altitude: aerial jumpers are relatively small compared to traditional aircraft, making them challenging to visually detect from a distance, especially when flying at higher altitudes or at low light/night. Radar systems are optimized for tracking larger targets, and the signals may not be sensitive enough to pick up the small and fast-moving profiles of individual aerial jumpers, and have terrain/line of sight limitations.
Lack of Transponders: Unlike most aircraft that are equipped with transponders for communication with radar systems and other aircraft, individual aerial jumpers do not typically carry such equipment. Transponders are crucial for broadcasting the aircraft's identity, position, altitude and other relevant information, enabling effective tracking via radar or ADS-B.
Free-fall Speed and Maneuverability: aerial jumpers descend at varying speeds during free-fall, and they have the ability to maneuver in three dimensions. This dynamic movement makes it challenging for radar systems to accurately track their positions in real-time, as the rapid changes in altitude and lateral movement can be difficult to predict and capture. ADS-B provides for excellent real time 3D movement tracking.
Limited Coverage in Low Altitude Areas: Radar coverage in lower altitude areas, especially in rural or sparsely populated regions, may be limited. This limitation further complicates the detection of aerial jumpers in areas where they may conduct jumps.
Visual Line-of-Sight Challenges: Pilots and air traffic controllers primarily rely on visual observations for detecting nearby aircraft. However, aerial jumpers, particularly when in free-fall, may not always be easily visible from the cockpit of an airplane due to factors such as cloud cover, visibility conditions, or the inherent challenge of spotting small objects against the vast background of the sky.
Communication Challenges: aerial jumpers in free-fall do not have direct communication with air traffic controllers or other aircraft. This lack of communication makes it difficult for air traffic controllers to provide timely information to pilots about the presence of aerial jumpers in the vicinity.

(J) DEFINITIONS

| | |
|---|---|
| aerial jumper | a person who engages in activities involving |
| | controlled free-fall and canopy flight |
| cavity | a hollow place within a body |
| container | A receptacle for holding items with an |
| | opening to introduce and take out these |
| | items |
| lid | An object which is movable so as to |
| | selectively open and close an opening of a |
| | container |
| port | An opening |

### DESCRIPTION OF THE INVENTION

### 1 Summary

The ParaDrop Operation Transponder (100) is a device that increases safety, visibility, and separation of paradrop operations by aircraft and air traffic controllers at high-volume airports and remote off-airport DZs (drop zones) for use at all altitudes and during night and day operations.

The ParaDrop Operation Transponder (100) allows for a) broader use of high-volume airports, remote and off-airport drop zones with increased safety, and b) expanded visibility and aerial separation protection by ATC. It provides drop zone safety officers (DZSO) real-time location and altitude of the aerial jumpers (90)—e.g. ForeFlight, ADS-B Exchange, FlightAware. Additional tracking might be available via ADS-B websites.

The ParaDrop Operation Transponder (100) provides aircraft the ability to avoid parachute canopies utilized during high speed free fall, all weather and/or night operations. When the aircraft cannot physically see the parachute canopies, the aircraft can still locate the ParaDrop Operation Transponder (100) location on their traffic in-cockpit screens in real time.

The ParaDrop Operation Transponder (100) comprises a main housing (200), a main circuit board (300), a secondary circuit board (600), a GPS transponder (700), a barometric connector (260), a power supply (360). The ParaDrop Operation Transponder (100) may further comprise conformal coating (390).

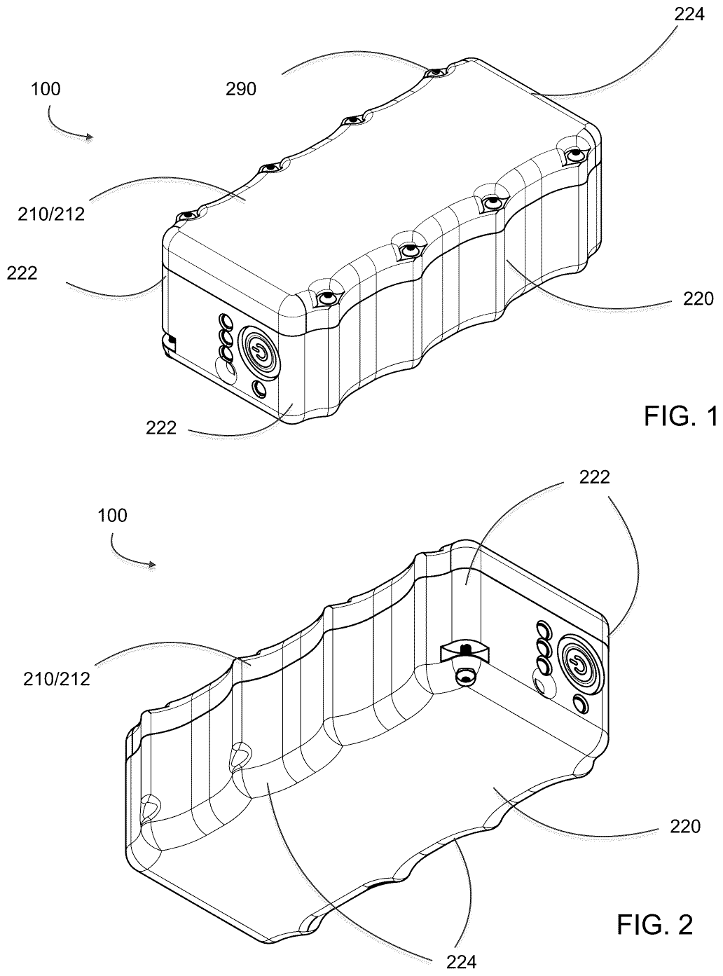

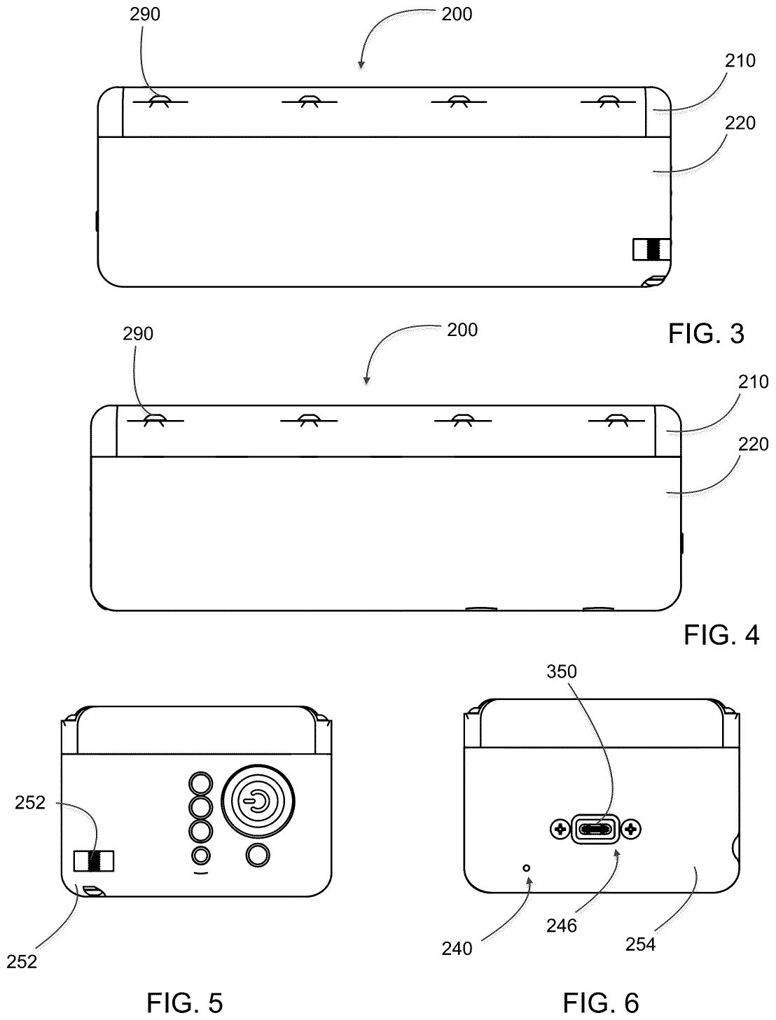

FIG. 1 and FIG. 2 show isometric views of the outside of the ParaDrop Operation Transponder (100). FIG. 3 shows a right view of the ParaDrop Operational Transponder (100). FIG. 4 shows a left view of the ParaDrop Operational Transponder (100). FIG. 5 shows a front view of the ParaDrop Operational Transponder (100). FIG. 6 shows a back view of the ParaDrop Operational Transponder (100).

### 2 Overview

The ParaDrop Operation Transponder (100) for aerial jumpers (90) solves the previously mentioned issues, making aerial jumpers (90) visible on traffic screens of aircraft in the vicinity and of air traffic controllers providing the separation services.

The ParaDrop Operation Transponder (100) provides a portable solution that meets or exceeds the current FAA ADS-B requirements.

It is crucial for pilots, air traffic controllers, and skydiving operators to establish effective communication channels and coordinate activities to enhance safety. NOTAMs are used to brief pilots about skydiving drop zones operating hours, however, a skydiving NOTAM is purely advisory in nature and covers a 20-30 mile area surrounding the drop zone and does not provide any real-time location or altitude of aerial jumpers (90) in the airspace at any given time.

### 3 Solved Issues

The integration of Automatic Dependent Surveillance-Broadcast (ADS-B) technology into the equipment of an aerial jumper (90) can bring several significant benefits for both pilots and air traffic controllers. ADS-B enhances situational awareness, improves communication, and contributes to overall airspace safety. While the implementation of ADS-B for individual aerial jumpers may pose logistical and technical challenges, the potential benefits in terms of enhanced safety and airspace management are substantial. Collaboration between the skydiving community, aviation regulators, and technology providers is essential to ensure the effective integration of ADS-B for all airspace users, including recreational parachutists.

### 3.1 Enhanced Situational Awareness for Pilots

Real-time Position Information: ADS-B allows the aerial jumper's precise position to be broadcasted periodically. This information is then made available to nearby aircraft equipped with ADS-B In capabilities. Pilots can receive accurate and up-to-date information about the location and altitude of the aerial jumper, contributing to enhanced situational awareness.
Collision Avoidance: Pilots, especially those flying at higher altitudes or in congested airspace, can receive alerts if their aircraft is on a collision course with an aerial jumper. This early warning system significantly improves the ability of pilots to take evasive action, reducing the risk of mid-air collisions.

### 3.2 Improved Air Traffic Management

Integration into Air Traffic Control Systems: Air traffic controllers can receive ADS-B information from equipped aerial jumpers, allowing them to have a more comprehensive view of all aircraft in the airspace, including individual jumpers. This enhanced awareness enables controllers to provide better instructions to pilots, manage traffic more efficiently, and issue timely advisories regarding the presence of aerial jumpers. ATC will have the ability to “see” the location of aerial jumpers and provide separation services to potential traffic conflicts in the area.
Coordination with Pilots: Air traffic controllers can use ADS-B data to coordinate the movements of aircraft and aerial jumpers, ensuring that jump activities are well-managed and integrated into the overall air traffic flow.

### 3.3 Increased Safety for Aerial Jumpers

Alerts to Nearby Aircraft: Equipping aerial jumpers with ADS-B provides an additional layer of safety. If a nearby aircraft is equipped with ADS-B In, the pilot will receive alerts about the presence of aerial jumpers in the vicinity, prompting them to exercise caution and maintain a safe distance.
Communication Facilitation: While aerial jumpers may not have direct communication with air traffic controllers, the ADS-B information they broadcast can serve as a virtual means of communication. Air traffic controllers and pilots can use this data to anticipate the movements of aerial jumpers and make informed decisions.

### 3.4 Integration with Existing Surveillance Systems

Seamless Integration: aerial jumpers equipped with ADS-B seamlessly integrate into existing air traffic surveillance systems, alongside traditional aircraft. This standardized approach ensures compatibility and interoperability within the airspace, promoting a cohesive and efficient air traffic management system.

### 3.5 Search and Rescue Operations

Location Information for Emergencies: In the rare event of an emergency or unexpected landing, ADS-B data from the aerial jumper's equipment can provide search and rescue teams with accurate location information, expediting response times and improving the chances of a successful rescue.
Stand-Alone Operation: The ParaDrop Operation Transponder (100) works as a stand-alone unit and does not rely on an aircraft's avionics system to operate.

### 3.6 Economics

Cost-Effectiveness: The ParaDrop Operation Transponder (100) is a cost-effective solution compared to traditional radar systems. The technology is more reliable, requires less maintenance, and offers greater coverage, especially in remote or oceanic areas. The ParaDrop Operation Transponder (100) is 100% GPS and barometer based, providing cost efficiency and approved technology benefits. The ParaDrop Operation Transponder (100) is also less impeded by terrain like traditional radar.

### 4 DETAILED DESCRIPTION

The ParaDrop Operation Transponder (100) comprises a main housing (200), a main circuit board (300), a secondary circuit board (600), a GPS transponder (700), a barometric connector (260), a power supply (360), a receiving antenna (370), a transmitting antenna (380) and a RF barrier (320). The ParaDrop Operation Transponder (100) may further comprise a circuit board housing (900). The ParaDrop Operation Transponder (100) may further comprise a lanyard (275). The ParaDrop Operation Transponder (100) may further comprise conformal coating (390).

FIG. 1 and FIG. 2 show isometric views of the outside of the ParaDrop Operation Transponder (100). FIG. 3 shows a right view of the ParaDrop Operational Transponder (100). FIG. 4 shows a left view of the ParaDrop Operational Transponder (100). FIG. 5 shows a front view of the ParaDrop Operational Transponder (100). FIG. 6 shows a back view of the ParaDrop Operational Transponder (100).

The main circuit board (300), the secondary circuit board (600), the GPS transponder (700), the power supply (360), the receiving antenna (370), and the transmitting antenna (380) are operationally connected either directly to each other or operationally connected through each other.

### 5 Main Housing (200)

The main housing (200) comprises a main lid (210), a main container (220), an O-ring (278), and a means to fasten lid to container (290). The main housing (200) may further comprise conductive sealant (280). The main housing (200) encloses elements of the ParaDrop Operation Transponder (100), protecting these elements from the environment, which consist of free-fall conditions, landing to ground stresses, and harsh temperature gradients. FIG. 3 shows the relative positioning of the main lid (210) with respect to the main container (220).

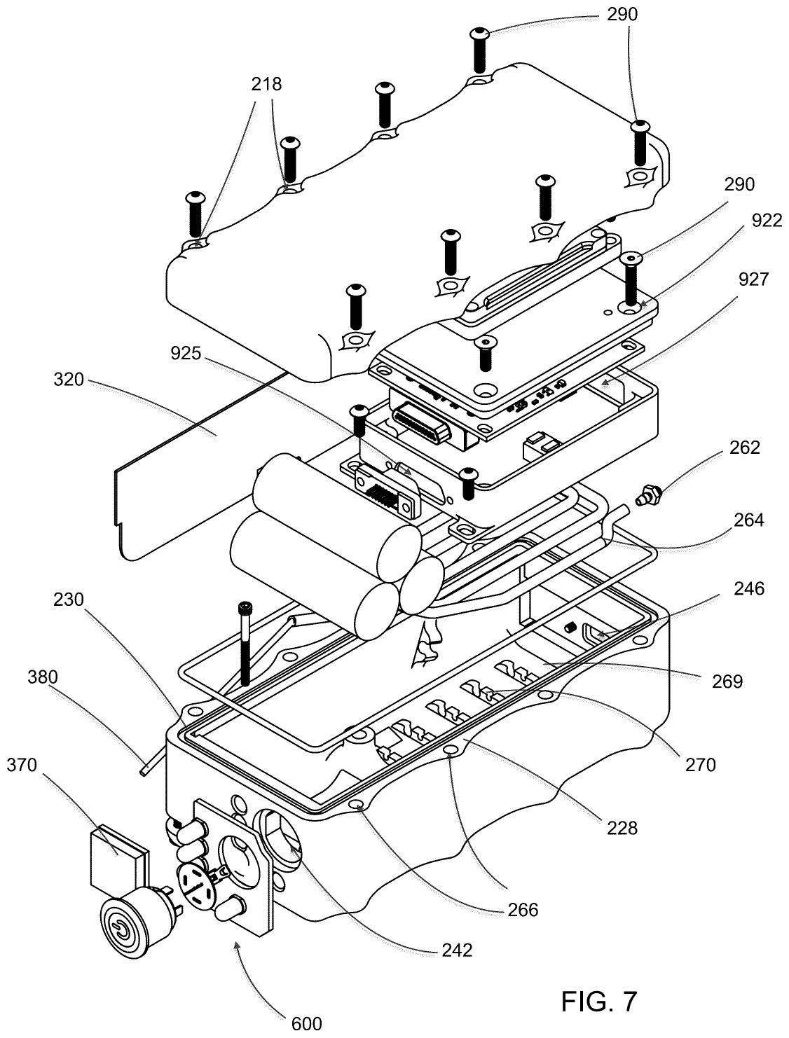

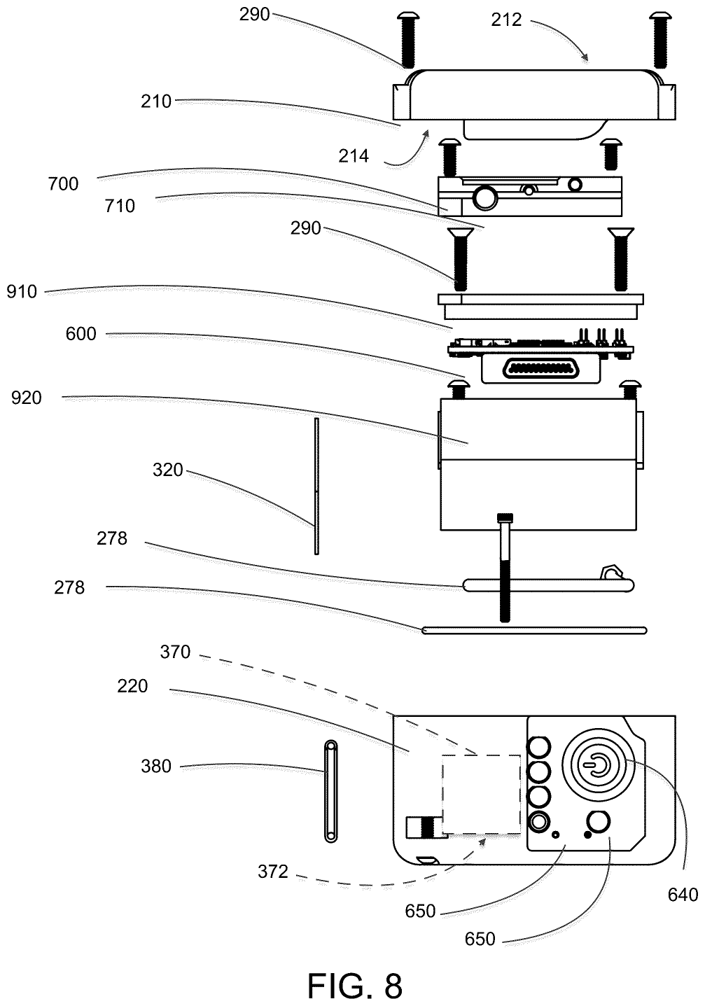

The main housing (200) contains the main circuit board (300), the secondary circuit board (600), the GPS transponder (700), the barometric connector (260), the power supply (360), the receiving antenna (370), the transmitting antenna (380) and the RF barrier (320). When present the main housing (200) contains the circuit board housing (900). FIGS. 7 and 8 show the relative positioning of the main circuit board (300), the secondary circuit board (600), the GPS transponder (700), the barometric connector (260), the power supply (360), the receiving antenna (370), the transmitting antenna (380) and the RF barrier (320) within the main housing (200).

### 5.1 Container (220)

The main container (220) comprises a main opening (226), a top perimeter surface (228), a barometric port (240), a power switch port (242), a power level status port (244), a data/power connector port (246), and a GPS status indicator port (256). FIG. 7 shows the main container (220), with its main opening (226), top perimeter surface (228), a barometric port (240), a power switch port (242), a power level status port (244), a data/power connector port (246), and a GPS status indicator port (256).

The main container (220) may further comprise rounded corners (222) and chamfered edges (224), providing the main container (220) with impact resistance and protection to the aerial jumper (90) in the event of the aerial jumper (90) falling over the unit during landing.

The walls that create the main opening (226) form a top perimeter surface (228) around the main opening (226). The top perimeter surface (228) comprises a closed loop channel (230). FIG. 7 shows a closed loop channel (230) formed on the top perimeter surface (228) of the walls formed by the main opening (226) of the main container (220).

The main container (220) may further comprise a first end (252) and a second end (254). The first end (252) is located on the opposite side of the second end (254).

The main container (220) may further comprise an inside bottom surface (269) and one or more fasteners (270). The one or more fasteners (270) are attached to the inside bottom surface (269) and secure the flexible section (264) of the barometric connector (260) described below. Securing the flexible section (264) of the barometric connector (260) to the inside bottom surface (269) prevents movement and removal from the attached elements and enables the functionality of the flexible section (264), that is, catching moisture and preventing such moisture from reaching the GPS transponder (700). The one or more fasteners (270) maybe attached over the inside bottom surface (269) of the main container (220). FIG. 7 shows the one or more fasteners (270) attached over the inside bottom surface (269) of the main container (220). The one or more fasteners (270) maybe molded into the inside bottom surface (269).

The main container (220) and the main lid (210) are made from materials that are impact resistant. The main container (220) and the main lid (210) are manufactured using state of art processes, including 3-D printing, mold extrusion, etc.

The main container (220) further comprises a barometric port (240), a power switch port (242), a power level status port (244), a data/power connector port (246), and a GPS status indicator port (256). These ports may be located as stand alone structures, or any port maybe merged with a combination of other ports. These ports are used to either access elements located inside the main container (220) or to secure elements to the main container (220).

The barometric port (240) allows barometric air pressure to access the GPS transponder (700) located within the main container (220) via the barometric connector (260).

The power switch port (242) provides access to the power switch (640), allowing the aerial jumper (90) to turn the ParaDrop Operation Transponder (100) on/off.

The data/power connector port (246) provides access to the outside data/power connector (350) of the main circuit board (300), allowing for recharge of the power supply (360) and data transfer from the main circuit board (300) and the GPS transponder (700).

The main container (220) further comprises a barometric connector (260). The barometric connector (260) provides a physical interface between the outside environment and the inside of the main container (220). This allows for the measurement of barometric air pressure from within the main container (220). The barometric connector (260) allows barometric air pressure to access the barometric input (710) of the GPS transponder (700) located inside the main container (220). Barometric air pressure is measured to assist the GPS transponder (700) in providing vertical position accuracy.

The barometric connector (260) comprises a rigid section (262) and a flexible section (264). The rigid section (262) is a tube that is press fit through the barometric port (240). The rigid section (262) is preferably manufactured from metal, specifically brass. The opening of the rigid section (262) is sized to prevent moisture from entering the flexible section (264) of the barometric connector (260), minimizing the effect of capillary action. The rigid section (262) is heat pressed through the barometric port (240).

The flexible section (264) is a tube that is connected to the barometric input (710) of the GPS transponder (700). The flexibility of the flexible section (264) allows the flexible section (264) to be coiled inside the main container (220). The one or more fasteners (270) maybe attached over the inside bottom surface (269). The fasteners (270) maybe molded into the inside bottom surface (269).

The flexible section (264) is preferable made from silicone. The length and coiled nature of the flexible section (264) of the barometric connector (260) prevents moisture from reaching the barometric input (710) of the GPS transponder (700) and the GPS transponder (700) itself, as the moisture gets caught in the coils. It is preferable that the flexible section (264) is coiled 2x to 5x, although greater coiling can also be suitable.

When the main container (220) comprises an inside bottom surface (269) and one or more fasteners (270), the flexible section (264) is attached to the one or more fasteners (270). These fasteners (270) allow for more effective coiling arrangements.

The rigid section (262) of the barometric connector (260) is pressed through the barometric port (240) of the main container (220). The flexible section (264) of the barometric connector (260) is connected to the barometric input (710) of the GPS transponder (700).

The main container (220) may further comprise a means to attach a lanyard (250). The means to attach a lanyard (250) is attached to the main container (220). This means to attach a lanyard (250) maybe any state-of-the-art connector, such as a pin, a ring, a clip, screw, etc. It allows a physical connection between the main container (220) and a lanyard (275). The lanyard (275) allows the aerial jumper (90) to attach the ParaDrop Operation Transponder (100) to a pocket/pouch/clip/other equipment that the aerial jumper (90) is already wearing for a skydive. If the ParaDrop Operation Transponder (100) is dropped or jarred loose from the aerial jumper's control, the ParaDrop Operation Transponder (100) will remain in physical connection with the aerial jumper (90) through the lanyard (275). The means to attach a lanyard (250) maybe permanently affixed to the main container (220) or maybe removable, such as a replaceable screw.

The main container (220) may further comprise a plurality of cavities (266) located around the perimeter of the main container (220). The location of the plurality of cavities (266) configured around the perimeter of the main container (220) mirrors that of the location of the plurality of cavities (218) configured around the perimeter of the main lid (210). FIG. 7 shows a plurality of cavities (266) located around the perimeter of the main container (220).

The means to fasten lid to container (290) are inserted through the cavities (218) of the main lid (210) into the cavities (266) of the main container (220) to ensure that the main lid (210) is fastened to the main container (220), creating a watertight seal between the main lid (210) and the main container (220).

### 5.2 Main Lid (210)

The main lid (210) comprises an outward facing side (212) and an inward facing side (214). The inward facing side (214) may comprise a closed loop channel (216). The closed loop channel (230) of the main container (220) has a similar profile as the closed loop channel (216) of the main lid (210).

The main lid (210) encloses the main opening (226) of the main container (220) so that when the main lid (210) and the main container (220) are fastened, this fastening creates a water-tight seal that prevents moisture from entering within the main container (220).

The main lid (210) may further comprise a plurality of cavities (218) located around the perimeter of the main lid (210). The location of the plurality of cavities (218) located around the perimeter of the main lid (210) mirrors that of the location of the plurality of cavities (266) located around the perimeter of the main container (220). FIG. 7 shows a plurality of cavities (218) located around the perimeter of the main lid (210). FIG. 7 shows how the location of the plurality of cavities (218) located around the perimeter of the main lid (210) mirrors that of the location of the plurality of cavities (266) located around the perimeter of the main container (220).

### 5.3 O-Ring (278)

The water-tight seal between the main lid (210) and the main container (220) is enhanced by placing an O-ring (278) between the main lid (210) and the main container (220).

The O-Ring (278) is fitted within the closed loop channel (230) of the main container (220) and placed against the inward facing side (214) of the main lid (210).

When the inward facing side (214) of the main lid (210) comprises a closed loop channel (216), the O-Ring (278) is fitted within the closed loop channel (230) of the main container (220) within and the closed loop channel (216) of the main lid (210).

The O-ring (278) is a loop of elastomer material with a cross-section. Example cross-sections include round, square and oval. The elastomer material deforms when pressure is applied, creating mechanical stress at the O-ring contacting surfaces the closed loop channel (230) of the main container (220) and the closed loop channel (216) of the lid (220) creating mechanical sealing.

### 5.4 Conductive Sealant (280)

The water-tight seal maybe further enhanced by having the O-ring (278) coated with a conductive sealant (280) (not shown). This conductive sealant (280) provides two functions: 1) waterproofing and 2) RF shielding.

Types of conductive sealants (280) that provide these two characteristics include:
1. Conductive Silicone Sealants—These are silicone-based sealants infused with conductive fillers (e.g., silver, nickel, or graphite). They provide flexibility, adhesion, and electrical conductivity for EMI shielding.
2. Conductive Epoxy Sealants—These are often used for bonding and sealing in harsh environments, offering durability, conductivity, and waterproofing. EMI Shielding Gaskets with Sealant Properties—Some elastomeric gaskets come with integrated conductive adhesive or sealant for both environmental and RF protection.
3. Conductive Polyurethane Sealants—Used for sealing electronic enclosures, antennas, and military applications, these sealants offer waterproofing along with RF shielding.

Types of Conductive Greases for Waterproofing & RF Shielding include:
1. Silver- or Nickel-Filled Conductive Grease-Provides excellent electrical conductivity and EMI/RF shielding. Used in high-performance applications like aerospace, military, and RF enclosures.
2. Graphite- or Carbon-Filled Conductive Grease Offers moderate conductivity at a lower cost. Suitable for automotive, industrial, and electronics applications.
3. Copper-Filled Conductive Grease. Provides a balance between conductivity and corrosion resistance. Commonly used for grounding and shielding in electrical connectors.
4. Silicone-Based Conductive Grease Provides strong waterproofing properties. Often used in outdoor electronics, antennas, and marine applications.

A specific type of a grease based conductive sealant (280) that provides these two functions is FelPro c5a copper conductive grease.

### 5.5 Means to Fasten Lid to Container (290)

To ensure that a lid is fastened to a container and that the watertight seal between the lid and the container is maintained, a means to fasten lid to container (290) is utilized.

The means to fasten lid to container (290) is any state-of-the-art fastening device that fastens and maintains two objects together. These state-of-the-art fastening devices should provide enough pressure to deform the O-Ring (278) so that the O-Ring (278) creates mechanical sealing between the main lid (210) and the main container (220).

As examples, the means to fasten lid to container (290) include bolts, a bolt and nut kit, clamps, clasps, and screws. Bolt types include eye bolts, wheel bolts and machine bolts, while types of nuts include cap nuts, expansion nuts, barrel nuts, and u-nuts.

To ensure that the main lid (210) is fastened to the main container (220) and that the watertight seal between the main lid (210) and the main container (220) is maintained, a means to fasten lid to container (290) is utilized.

To ensure that the circuit board lid (910) is fastened to the circuit board container (920) and that the watertight seal between the circuit board lid (910) is fastened to the circuit board container (920) is maintained, a means to fasten lid to container (290) is utilized.

FIG. 1 shows the means to fasten lid to container (290) fastening the main lid (210) to the main container (220). FIG. 8 shows the relative positioning of the means to fasten lid to container (290), the circuit board lid (910), and the circuit board container (920) in an exploded view.

### 6 Circuit Board Housing (900)

The circuit board housing (900) protects the elements enclosed within the circuit board housing (900) from RF interference. The elements within the main housing (200) are packed tightly and are subject to considerable RF interference radiating from the transmitting antenna (380), the receiving antenna (370), and the GPS transponder (700). If not addressed, this interference leads to faulty main circuit board (300) operations. Hence, there is a need to protect the main circuit board (300) from this RF interference.

The circuit board housing (900) comprises a circuit board lid (910), a circuit board container (920), and means to fasten lid to container (290). When the circuit board housing (900) is present, the main circuit board (300) is enclosed within the circuit board housing (900). FIG. 8 shows the relative positioning of the means to fasten lid to container (290), the circuit board lid (910), and the circuit board container (920) in an exploded view.

### 6.1 Circuit Board Lid (910)

The circuit board lid (910) may comprise a plurality of cavities (912), where the plurality of cavities (912) is arranged around the perimeter of the circuit board lid (910).

### 6.2 Circuit Board Container (920)

The circuit board container (920) comprises an inside data/power connector port (925), an outside data/power connector port (927). The inside data/power connector port (925) allows for an operational connection between the main circuit board (300) and the other elements requiring an operational connection with the main circuit board (300), that is the GPS transponder (700), the secondary circuit board (600), and the power supply (360). The outside data/power connector port (927) allows for an operational connection between the main circuit board (300) and outside elements that connect the outside data/power connector (350) of the main circuit board (300).

The circuit board container (920) may further comprise a plurality of cavities (922), where the plurality of cavities (922) is arranged around the perimeter of the circuit board container (920).

When the circuit board lid (910) comprises a plurality of cavities (912) and the circuit board container (920) comprises a plurality of cavities (922), the means to fasten lid to container (290) of the circuit board housing (900) are placed through the plurality of cavities (912) of the circuit board lid (910) of the circuit board housing (900) and through the plurality of cavities (922) of the circuit board container (920) of the circuit board housing (900). FIG. 8 show the means to fasten lid to container (290) of the circuit board housing (900) placed through the plurality of cavities (912) of the circuit board lid (910) of the circuit board housing (900) and through the plurality of cavities (922) of the circuit board container (920) of the circuit board housing (900).

The circuit board container (920) is aligned to the main container (220) so that the outside data/power connector port (927) of the circuit board container (920) is aligned to the data/power port (246) of the main container (220).

The circuit board housing (900) is made from materials that shield partly or fully the main circuit board (300) from RF interference. Materials that shield RF interference are typically conductive and/or magnetic. Some of the most common and effective options:

Metals: Copper: Excellent conductor, highly effective at blocking RF signals. Can be expensive but is a top choice for high-performance shielding. Aluminum: Lightweight and cost effective, good for applications where weight is a concern. Less conductive than copper but still provides decent shielding. Steel: Offers magnetic shielding in addition to RF shielding, making it suitable for low-frequency interference. Sturdy and durable. Nickel Silver: A copper alloy with good corrosion resistance, often used in harsh environments. Brass: Another copper alloy, offers a balance of conductivity, corrosion resistance, and affordability. Gold: Excellent conductor, particularly effective at high frequencies. Often used for plating in specialized applications.

Other Materials: Conductive Elastomers: Elastomers like silicone can be made conductive by filling them with metal particles (e.g., silver, nickel). Used in gaskets and seals to block RF leakage. Conductive Fabrics: Fabrics woven with conductive fibers can be used for shielding enclosures or wrapping cables. Metal Foils: Thin sheets of metal (aluminum, copper) can be used to wrap cables or line enclosures. Conductive Coatings: Paints or sprays containing conductive particles can be applied to surfaces to create a shielding layer.

### 7 Circuit Boards

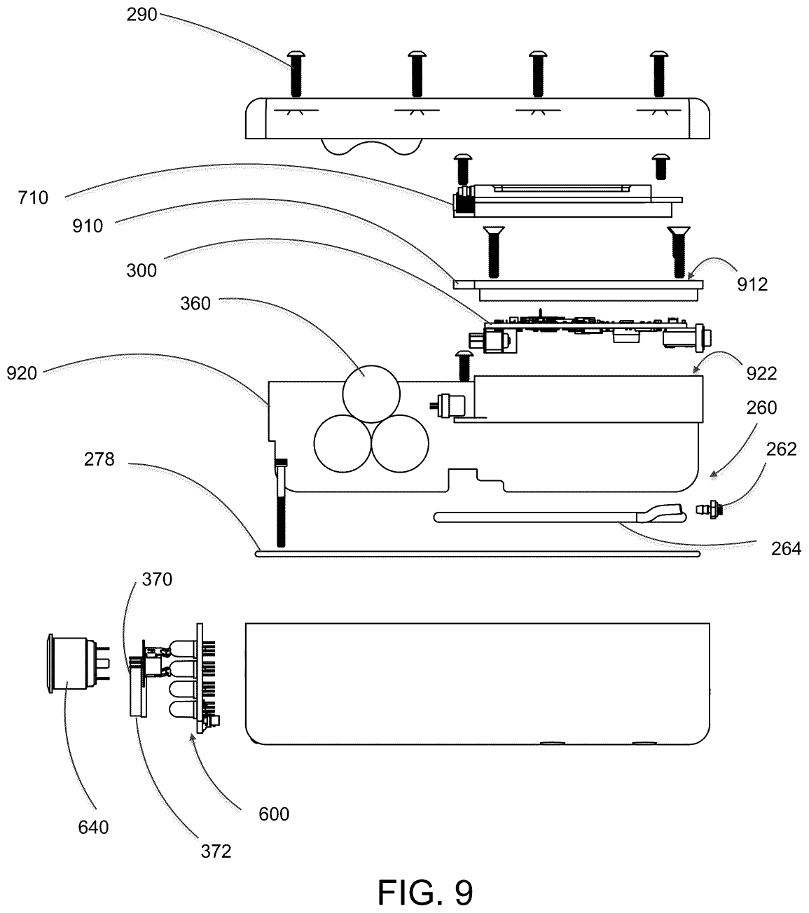

Within the ParaDrop Operation Transponder (100), two circuit boards exist: the main circuit board (300) and the secondary circuit board (600). FIG. 7 and FIG. 9 show the relative positioning of the main circuit board (300) and the secondary circuit board (600).

Electrical components are connected to either the main circuit board (300) or the secondary circuit board (600) to increase space availability and to make component replacement easier. By splitting the allocation of specific electrical components to either the main circuit board (300) or the secondary circuit board (600), the design allows to RF interference minimization between various groups of electrical components.

The main circuit board (300) is contained and attached within the main housing (200). When a circuit board housing (900) is present, the main circuit board (300) is contained and attached within the circuit board housing (900). The main circuit board (300) is located away from the secondary circuit board (600) to minimize RF interference between the two boards.

The secondary circuit board (600) is contained and attached within the main housing (200). The secondary circuit board (600) is located towards the second end (254) of the main container (220).

The secondary circuit board (600) maybe oriented horizontally or vertically. When oriented vertically, the secondary circuit board (600) is perpendicular to the inward facing side (214) of the main lid (210) when the main lid (210) and the main container (220) are fastened. The vertical orientation saves space and enables the main container (220) to have a smaller form factor. The smaller form factor is highly beneficial as it reduces the bulk carried by the aerial jumper (90). In many applications, such as military operations, bulk minimization is fundamental.

### 8 Main Circuit Board (300)

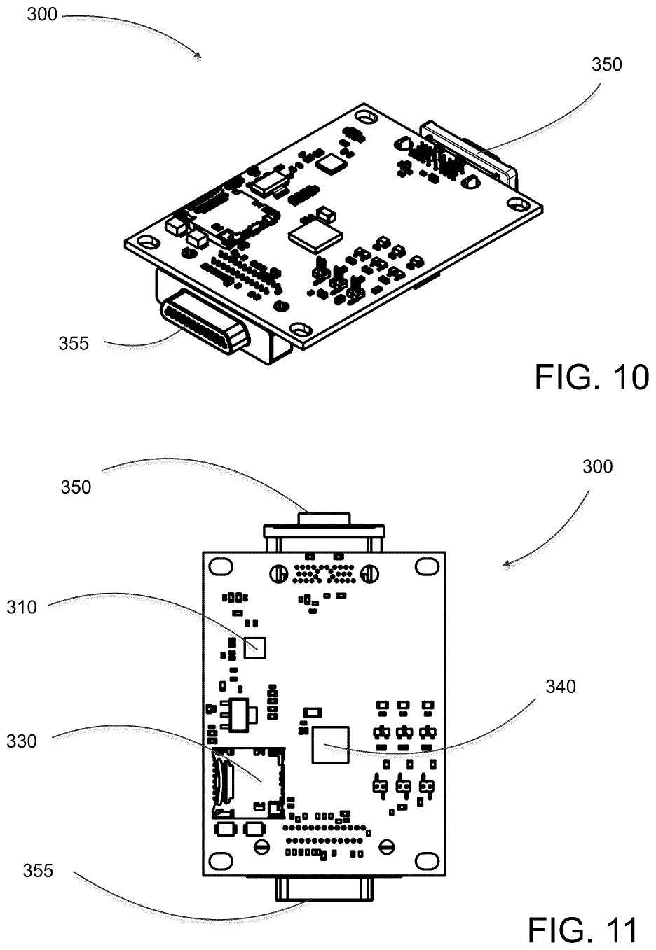

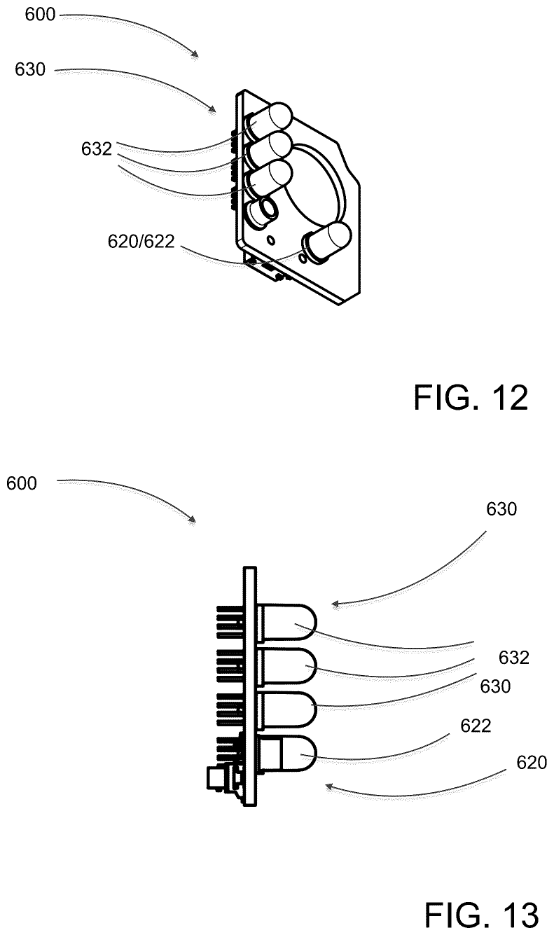

The main circuit board (300) comprises a controller (330), a battery management system (340), an outside data/power connector (350), and an inside data/power connector (355). The main circuit board (300) may further comprise memory (310). FIG. 10 and FIG. 11 show an isometric and top view of the main circuit board (300).

### 8.1 Battery Management System (340)

The power supply (360) requires a battery management system (340) on the main circuit board (300). The battery management system (340) manages the power supply (360) during charging and during discharging. The battery management system (340) keeps the power supply (360) balanced and updates the power level status indicator (630). If the power supply (360) is discharged below a preset threshold, the battery management system (340) will not allow the unit to be turned on until the power supply (360) is charged again. This ensures adequate power supply for each use. FIG. 11 show a representative positioning of the battery management system within the main circuit board (300).

### 8.2 Outside Data Power Connector (350)

The outside data/power connector (350) allows for data/power transmission in and out of the main circuit board (300) to the outside environment and power charging through the battery management system (340) into the power supply (360). The data transmission allows the GPS transponder (700) to be connected to a laptop or desktop computer for initial power up, settings and quality control/functional checks/service or trouble shooting & future firmware updates. An example of an outside data/power connector (350) are USB-A, USB-B, and USB-C connectors. FIG. 11 shows the relative positioning of the outside data/power connector (350) within the main circuit board (300).

When contained within the circuit board housing (900), the outside data/power connector (350) is positioned within the outside data/power connector port (927) of the circuit board container (920). The outside data/power connector (350) maybe waterproof sealed to prevent moisture and water to enter the circuit board container (920).

### 8.3 Inside Data Power Connector (355)

The inside data/power connector (355) allows for data/power transmission in and out of the main circuit Board (300) to the inside environment such as the GPS transponder (700), the power supply (360), the receiving antenna (370) and the transmitting antenna (380). FIG. 11 shows the relative positioning of the inside data/power connector (355) within the main circuit board (300).

When contained within the circuit board housing (900), the inside data/power connector (355) is positioned within the inside data/power connector port (925) of the circuit board container (920). The inside data/power connector (355) maybe waterproof sealed to prevent moisture and water to enter the circuit board container (920).

### 8.4 Memory (310)

A data storage option is contemplated for the main circuit board (300). The memory within the main circuit board (300) would be designed as a stand alone module or incorporated within a larger chip architecture. FIG. 11 shows the relative positioning of the memory (310) within the main circuit board (300) when the memory is a stand alone module.

### 9 Power Supply (360)

The power supply (360) provides power to the components requiring power to operate the ParaDrop Operation Transponder (100), including the main circuit board (300), the secondary circuit board (600), the GPS transponder (700), the receiving antenna (370), and the transmitting antenna (380). The power supply (360) is operatively connected to these components. FIG. 7 shows an exploded view of the ParaDrop Operation Transponder (100), showing the relative positioning of the power supply (360).

The power supply (360) any state of art rechargeable energy storage device, depending on the desired power supply characteristics. When electro-chemical solutions are chosen, any of state-of-the-art rechargeable electro-chemistry can be used, including but not limited to lithium hybrid and lithium ion chemistries. The selection of rechargeable energy storage device and manufacturing technique should allow the power supply (360) to be safe to use, that is, to mechanically sustain high impact, to be energy stable on high impact, and to be inert upon power supply puncture.

Given the harsh environment that the ParaDrop Operation Transponder (100) is utilized in, opening the ParaDrop Operation Transponder (100) may reduce optimal main lid (210) and main container (220) sealing characteristics. The use of rechargeable batteries eliminates this need to open the ParaDrop Operation Transponder (100) to replace non-chargeable batteries.

Preferably, the power supply (360) should be sized to allow for a nine (9) hour run time. The power supply (360) requires a battery management system (340) on the main circuit board (300). The battery management system (340) manages the power supply (360) during both normal charging and/or during normal discharging while in use.

The battery management system (340) keeps the power supply (360) adequately charged for optimal charging and discharging, changes the color of the one or more LED lights (632) when the charge cycle is complete in the power level status indicator (630), and may also display the power supply (360) health on the power level status indicator (630) during both charging and normal use. Finally, if the unit is discharged below a preset threshold, the battery management system (340) will not allow the ParaDrop Operation Transponder (100) to be turned on until the power supply (360) of the ParaDrop Operation Transponder (100) is charged over a predetermined level (e.g. 90%). This ensures adequate power supply for each use of the ParaDrop Operation Transponder (100).

### 10 Receiving Antenna (370)

The receiving antenna (370) receives data to be passed on to the GPS transponder (700) for accurate position signal (airspeed, altitude & trajectory). The receiving antenna (370) may further comprise a conductive metal plate (372). This conductive metal plate (372) increases the surface area of the receiving antenna (370) to improve GPS acquisition time.

The receiving antenna (370) lies within the main container (210). FIG. 8 shows an exploded front view of the ParaDrop Operation Transponder (100), showing the inside positioning of the receiving antenna (370) within the main container (220). The conductive metal plate (372) is positioned in the bottom section of the receiving antenna (370). FIG. 9 shows an exploded side view of the ParaDrop Operation Transponder (100), showing the exploded position of the receiving antenna (370).

### 11 Transmitting Antenna (380)

The GPS transponder (700) transmits its position via the transmitting antenna (380). The positional data is transmitted along with an identifier e.g. —“PARACHUT”— and an FAA general aviation squawk code—e.g. 1200. The identifier and squawk code is entered at the unit's first power up and is not changeable unless cabled to an online computer. The default name “PARACHUT” is used because it uses the maximum of 8 characters) This position information can be seen on ADS-B/Mode-S/TCAS equipped aircrafts' traffic screens, ATC equipment, independent navigation devices such as tablets with Foreflight, Garmin Pilot, FlightPlanGo, and internet based sites such as Flight Aware, ADS-B Exchange, and Flight Radar24. As an example, the transmitting antenna (380) can be an omnidirectional ADS-B 1090 MHZ device. FIG. 7 shows an exploded top front right isometric view of the ParaDrop Operation Transponder (100), showing the exploded position of the transmitting antenna (380). FIG. 8 shows an exploded front view of the ParaDrop Operation Transponder (100), showing the exploded position of the transmitting antenna (380).

### 12 Conformal Coating (390)

The main circuit board (300) and the secondary circuit board (600) maybe coated with a conformal coating (390) (not shown). This conformal coating (390) provides impact protection, waterproofing and RF interference reduction.

### 13 RF Barrier (320)

The RF Barrier (320) is located between the transmitting antenna (380) and the circuit board housing (900). The RF Barrier (320) prevents RF from the transmitting antenna (380) from causing interference to the GPS transponder (700) and the main circuit board (300) during transmission through the transmitting antenna (380). The RF Barrier (320) is oriented vertically relative to the main lid (210). The RF Barrier (320) is made from materials that are non-conductive. The choice of non-conductive materials is for insulation and separation purposes. Non-conductive materials, also known as dielectrics or insulators, are essential for separating conductive elements in a shielding structure. This prevents short circuits and allows the shield to function effectively. Because some of the components housed within the main container (220) have conductive characteristics—e.g. Circuit Board Housing (900)—these components need to be physically separated from the transmitting antenna (380).

Examples of non-conductive materials used in RF Shielding include: Silicone: Flexible, temperature-resistant, and provides good sealing properties. Often used in gaskets and seals; Rubber (Neoprene, EPDM): Offers good sealing and cushioning. Can be used in gaskets or as a base for conductive coatings; Foam: Lightweight and compressible. Used for cushioning, filling gaps, and sometimes as a core material in shielding structures; Plastics: Certain types of plastics can be used as structural components in RF shields, providing support and insulation for conductive layers; Ceramics: Offer excellent electrical insulation and can be used in high-frequency applications.

### 14 Secondary Circuit Board (600)

The secondary circuit board (600) comprises a GPS status indicator (620), a power switch (640), a power level status indicator (630). The secondary circuit board (600) regulates power to these components. The secondary circuit board (600) may further comprise conformal coating (390). FIG. 9 shows an exploded side view of the secondary circuit board (600).

The positioning of the secondary circuit board (600) relative to the main circuit board (300) isolates from RF interference electrical components from one board to the other board. The secondary circuit board (600) governs power to the power switch (640), the GPS status indicator (620), and the power level status indicator (630).

The secondary circuit board (600) may further comprise a photocell (650).

### 14.1 GPS Status Indicator (620)

The GPS status indicator (620) indicates the health and signal strength of the GPS. The GPS status indicator (620) is positioned within the GPS status indicator power port (256) and waterproof sealed to the GPS status indicator power port (256) to prevent moisture and water to enter the main container (220). The GPS status indicator (620) comprises one or more LEDs (622).

### 14.2 Power Level Status Indicator (630)

The power level status indicator (630) indicates the battery charge for the power supply (360). The power level status indicator (630) is positioned within the power level status port (244) and waterproof sealed to the power level status port (244) to prevent moisture and water to enter the main container (220). The power level status indicator (630) comprises one or more LEDs (632).

When one LED (632) is used, the LED (632) glows one color—e.g. green—to indicate an operational level of power. The LED (632) glows another color—e.g. red—to indicate a non-operational level of power.

When two LEDs (632) are used, one LED (632) glows one color—e.g. green—to indicate an operational level of power. The other LED (632) glows another color—e.g. red—to indicate non-operational level of power. One or the other LEDs (632) glows at a given time.

When more than two LEDs are used, the number of lit LEDs can be used to indicate a level of power available for the ParaDrop Operation Transponder (100).

### 14.3 Power Switch (640)

The power switch (640) turns on/off the power for the ParaDrop Operation Transponder (100). The Power Switch (640) is positioned within the power switch port (242) and waterproof sealed to the power switch port (242) to prevent moisture and water to enter the main container (220). The power switch (640) may light up when pressed to indicate the power status of the ParaDrop Operation Transponder (100). FIG. 8 shows the positioning of the power switch (640) in a front view of the secondary circuit board (600) and the ParaDrop Operation Transponder (100).

### 14.4 Photocell (650)

The photocell (650) automatically dims the GPS status indicator (620) and the power level status indicator (630) in relation to the ambient light encountered during use. This photocell (650) will auto-dim all of the led lights of the GPS status indicator (620) and the power level status indicator (630) during night/reduced light use, mainly for use with night vision goggles worn by the users. FIG. 8 shows the positioning of the photocell (650) relative to the other components of the secondary circuit board (600).

### 15 GPS Transponder (700)

A transponder (short for transmitter-responder and sometimes abbreviated to XPDR, XPNDR, TPDR or TP) is an electronic device that produces a response when it receives a radiofrequency interrogation. Aircraft have transponders to assist in identifying them on air traffic control radar. Collision avoidance systems have been developed to use transponder transmissions as a means of detecting aircraft at risk of colliding with each other.

Air traffic control units use the term “squawk” when they are assigning an aircraft a transponder code, e.g., “Squawk 7421”. Squawk thus can be said to mean “select transponder code” or “squawking xxxx” to mean “I have selected transponder code xxxx”. An aircraft transponder receives interrogation from the Secondary Surveillance Radar on 1030 MHz and replies on 1090 MHz.

The GPS transponder (700) is an ADS-B/Mode-S out device that enables the aerial jumper (90) to be detected by Secondary Surveillance Radar (SSR), Traffic Collision Avoidance Systems (TCAS), and ADS-B IN receivers. The GPS transponder (700) provides ADS-B Out only, as the aerial jumper (90) does not have the radio capability to communicate with airplanes.

The GPS transponder (700) is enclosed within the main container (220). The transponder is preferably horizontally attached to the circuit board housing (900). The GPS transponder (700) is operationally attached to the main circuit board (300). FIG. 8 shows the positioning of the GPS transponder (700) relative to the other components of the main housing (200).

The GPS transponder (700) further comprises a barometric input (710). The barometric input (710) allows the transponder to calculate altitude as a function of the barometric air pressure. The barometric input (710) is connected to the flexible section (264) of the barometric connector (260).

The GPS transponder (700) maybe equipped with a Satellite-based Augmentation System (SBAS) for accurate position signal (airspeed, altitude & trajectory). The information received by the receiving antenna (370) is crossed checked with the ambient barometric pressure data obtained from the barometric input (710) for vertical accuracy. The Source Integrity Level (SIL) 3 GPS data output guarantees integrity and visibility to certified avionics in ADS-B or Mode-S equipped aircraft and Air Traffic Control.

The rigid section (262) of the barometric connector (260) is pressed through the barometric port (240) of the main container (220). The flexible section (264) of the barometric connector (260) is connected to the barometric input (710) of the GPS transponder (700).

### 16 Clarifying Comments

While the foregoing written description of the invention enables a person having ordinary skill in the art to make and use what is considered presently to be the best mode thereof, those of ordinary skill in the art will understand and appreciate the existence of variations, combinations, and equivalents of the specific embodiment, process, and examples herein. The invention should therefore not be limited by the above described embodiment, process, and examples, but by all embodiments and processes within the scope and spirit of the invention.

The inventions shown and described herein may be used to address one or more of such problems or other problems not set out herein and/or which are only understood or appreciated at a later time. The future may also bring to light currently unknown or unrecognized benefits which may be appreciated, or more fully appreciated, in association with the inventions shown and described herein. The desires and expected benefits explained herein are not admissions that others have recognized such prior needs, since invention and discovery are both inventive under the law and may relate to the inventions described herein.

1. A device utilized by an aerial jumper to provide real-time locational awareness to aircraft and control towers, the device comprising:
(a) a main housing; the main container comprising:
(i) a main lid; the main lid comprising:
(1) an outward facing side;
(2) an inward facing side;
(ii) a main container; the main container comprising
(1) a main opening;
(2) a top perimeter surface, the top perimeter surface comprising a closed loop channel;
(3) a barometric port;
(4) a power switch port;
(5) a power level status port;
(6) a data/power connector port;
(7) and a GPS status indicator port;
(iii) an O-ring; and
(iv) a means to fasten lid to container;
(v) where the O-ring fits within the close loop channel of the top perimeter surface of the main container, providing a water-tight seal between the main lid and the main container when the means to fasten lid to container fastens the main lid to the main container;
(b) a main circuit board, the main circuit board comprising:
(i) a battery management system;
(ii) an inside data/power connector; and
(iii) an outside data/power connector;
(c) a secondary circuit board; the secondary circuit board comprising:
(i) a power switch;
(ii) a power level status indicator; and
(iii) a GPS status indicator;
(iv) where the power switch is accessed through the power switch port of the main container,
(v) where the power level status indicator is accessed through the power level status port of the main container,
(vi) where the GPS status indicator is accessed through the GPS status indicator port of the main container,
(d) a GPS transponder; the GPS transponder comprising:
(i) a barometric input;
(ii) where the GPS transponder is equipped with a satellite-based augmentation system;
(e) a circuit board housing; the circuit board housing comprising
(i) a circuit board lid;
(ii) a circuit board container; the circuit board container comprising:
(1) an inside data/power connector port; and
(2) an outside data/power connector port; and
(iii) a means to fasten lid to container;
(iv) where the main circuit board is located within the circuit board container;
(f) a barometric connector, the barometric connector comprising:
(i) a rigid section; and
(ii) a flexible section;
(iii) where the rigid section is attached to the barometric port of the main container,
(iv) where the flexible section is attached to the barometric input of the GPS transponder;
(g) a power supply;
(h) a receiving antenna;
(i) a transmitting antenna; and
(j) a RF barrier;
(i) where the RF barrier is located between the transmitting antenna and the circuit board housing;
(ii) where the RF barrier blocks the RF interference from the transmitting antenna to the main circuit board;

2. The device described in claim 1,
(a) wherein the main lid of the main housing comprises a plurality of cavities arranged around the perimeter of the main lid of the main housing;
(b) wherein the main container of the main housing comprises a plurality of cavities arranged around the perimeter of the main container;
(c) where the means to fasten a lid to a container of the main housing are placed through the plurality of cavities of the main lid of the main housing and through the plurality of cavities of the main container of the main housing;
(d) wherein the circuit board lid of the circuit board housing comprise a plurality of cavities arranged around the perimeter of the circuit board lid;
(e) wherein the circuit board container of the circuit board housing comprises a plurality of cavities arranged around the perimeter of the circuit board container;
(f) where the means to fasten a lid to a container of the circuit board housing are placed through the plurality of cavities of the circuit board lid of the circuit board housing and through the plurality of cavities of the circuit board container of the circuit board housing.

3. The device described in claim 2,
(a) the device further comprising a lanyard;
(b) wherein the main container of the main housing further comprises a means to attach a lanyard to a container;
(c) where the lanyard is attached to the main container through the means to attach a lanyard to a container.

4. The device described in claim 2,
(a) wherein the secondary circuit board further comprises:
(i) a photocell;
(ii) where the photocell controls the LEDs of the power level indicator and the GPS status indicator of the secondary circuit board.

5. The device described in claim 2,
(a) where the inner facing side of the main lid of the main housing comprises:
(i) a closed loop channel;
(b) where the O-ring fits within the closed loop channel of the inner surface of the lid of the main housing when the main housing lid and the main housing container are fit together.

6. The device described in claim 2,
(a) wherein the main container of the main housing further comprises:
(i) an inside bottom surface; and
(ii) one or more fasteners;
(b) where the flexible section of the barometric connector is attached to the one or more fasteners of the inside bottom surface of the main housing.

7. The device described in claim 6,
(a) where the one or more fasteners are molded into the inside bottom surface of the main container.

8. The device described in claim 2,
(a) wherein the main container further comprises:
(i) rounded corners; and
(ii) chamfered edges;
(b) where the rounded corners and the chamfered provide impact resistance and protection to the aerial jumper in the event the aerial jumper falling over the device during landing.

9. The device described in claim 7,
(a) wherein the secondary circuit board further comprises:
(i) a photocell;
(ii) where the photocell controls the LEDs of the power level indicator and the GPS status indicator of the secondary circuit board.

10. The device described in claim 9,
(a) wherein the primary circuit board further comprises memory.

11. The device described in claim 2,
(a) wherein the secondary circuit board further comprises:
(i) a photocell;
(ii) where the photocell controls the LEDs of the power level indicator and the GPS status indicator of the secondary circuit board;
(b) wherein the main container of the main housing further comprises:
(i) an inside bottom surface; and
(ii) one or more fasteners;
(c) where the flexible section of the barometric connector is attached to the one or more fasteners of the inside bottom surface of the main housing;
(d) wherein the primary circuit board further comprises memory.

12. The device described in claim 3,
(a) wherein the secondary circuit board further comprises:
(i) a photocell;
(ii) where the photocell controls the LEDs of the power level indicator and the GPS status indicator of the secondary circuit board;
(b) wherein the main container of the main housing further comprises:
(i) an inside bottom surface; and
(ii) one or more fasteners;
(c) where the flexible section of the barometric connector is attached to the one or more fasteners of the inside bottom surface of the main housing;
(d) wherein the primary circuit board further comprises memory.

13. The device described in claim 1,
(a) wherein the secondary circuit board further comprises:
(i) a photocell;
(ii) where the photocell controls the LEDs of the power level indicator and the GPS status indicator of the secondary circuit board;
(b) wherein the main container of the main housing further comprises:
(i) an inside bottom surface; and
(ii) one or more fasteners;
(c) where the flexible section of the barometric connector is attached to the one or more fasteners of the inside bottom surface of the main housing;
(d) wherein the primary circuit board further comprises memory.
